(19) United States
(12) Patent Application Publication
(10) Pub. No.: US 2026/0332865 A1
(43) Pub. Date: Oct. 22, 2026

(54) CAMERA DEVICE EASY TO ASSEMBLE AND TRANSPORT

(71) Applicant: SHENZHEN CHENGXIN INTELLIGENT EQUIPMENT CO., LTD., SHENZHEN (CN)

(72) Inventor: LIHONG LIANG, SHENZHEN (CN)

(21) Appl. No.: 19/553,250

(22) Filed: Feb. 28, 2026

(30) Foreign Application Priority Data
Feb. 28, 2025 (CN) 202520341548.6

(51) Int. Cl. H04N 23/51; G03B 15/05; H04N 23/53; H04N 23/56; H05K 5/02; H04N 1/00

(52) U.S. Cl. CPC H04N 23/51; G03B 15/05; H04N 23/531; H04N 23/56; H05K 5/0234; G03B 2215/0557; H04N 1/00251; H04N 1/00265

(57) ABSTRACT

A camera device easy to assemble and transport includes a display module, a camera module, a side fill light, a foldable support frame, universal wheels, a tray, and a main control module. A light-transmitting mirror layer is disposed on an end surface of the display module. A display screen is disposed adjacent to the light-transmitting mirror layer. The camera module is detachably connected to the display module. The side fill light is disposed on a side end of the display module and detachably connected to the display module. The foldable support frame is detachably connected to the display module. The universal wheels and the tray are detachably connected to the foldable support frame. The display screen and the camera module are electrically connected to the main control module. An operation interaction module electrically connected to the main control module is disposed on the light-transmitting mirror layer.

### TECHNICAL FIELD

The present disclosure relates to a field of photographic and video recording devices, and in particular to a camera device easy to assemble and transport.

### BACKGROUND

Currently, smartphones have fully met daily selfie needs of users. However, when there is a need to capture photos of specific sizes (such as ID photos), users often need to resort to professional photo booths, as photo booths are able to efficiently complete a capturing process and quickly print out photos that meet specifications. Nevertheless, photo booths are typically fixed indoors and unable to capture outdoor scenery into the photos, resulting in limited shooting scenes.

On the other hand, if users wish to capture broader scenery or take group photos with multiple people by a smartphone, they must either seek help from passers-by or use a selfie stick, both of which cause inconvenience. Moreover, the selfie stick often appears in a frame when taking a selfie, undermining aesthetic of the photos. Additionally, a brightness of a smartphone flash is limited, making it difficult to achieve ideal portrait effects in low-light conditions, and the smartphone is impossible to print the photos immediately after capturing.

While users may use an instant camera as a substitute for the smartphone to print photos immediately after shooting, the users still need to ask passers-by for help or use the selfie stick if they want to include more scenery in the frame or take group photos with multiple people. Similarly, a brightness of a flash on the instant camera is limited and is unable to provide sufficient fill light for high-quality portrait effects. Furthermore, carrying the instant camera increases a carrying burden for the users.

Therefore, there is an urgent need for a camera device that not only overcomes bulkiness and scene limitations of conventional photo booths but also compensates for deficiencies of the smartphone and the instant camera in terms of framing, shooting effects, and instant printing.

### SUMMARY

The present disclosure provides a camera device easy to assemble and transport to solve technical problems in the prior art.

The camera device easy to assemble and transport comprises a display module, a camera module, a front fill light, a side fill light, a foldable support frame, universal wheels, a tray, and a main control module. A light-transmitting mirror layer is disposed on an end surface of the display module. A display screen is disposed adjacent to the light-transmitting mirror layer.

The camera module is detachably connected to the display module. The side fill light is disposed on a side end of the display module and detachably connected to the display module. The foldable support frame is detachably connected to a rear side of the display module. The universal wheels are detachably connected to a lower end of the foldable support frame. The tray is detachably connected to the foldable support frame when the foldable support frame is unfolded. The main control module is disposed in the display module. The display screen and the camera module are electrically connected to the main control module. An operation interaction module electrically connected to the main control module is disposed on an end surface of the light-transmitting mirror layer.

The front fill light is in a closed ring shape or a non-closed ring shape, and the front fill light is disposed along edges of the display module or adjacent to the edges of the display module.

Furthermore, the display module is rectangular and tilted at an angle of 70°.

Furthermore, the display module further comprises a support middle frame, a support skeleton, and a rear cover plate. The light-transmitting mirror layer and the rear cover plate are respectively disposed on two end surfaces of the support middle frame. The support skeleton is enclosed by the light-transmitting mirror layer and the support middle frame. The support skeleton is connected to the support middle frame. The display screen and the main control module are mounted on the support skeleton.

Furthermore, the camera module comprises a protective replacement box, an adjusting base, and a capturing camera. The adjusting base and the capturing camera are disposed in the protective replacement box. The capturing camera is connected to the protective replacement box through the adjusting base. The protective replacement box is detachably connected to the rear cover plate. The light-transmitting mirror layer comprises a image-capturing opening corresponding to the capturing camera. A locking door is rotatably connected to the protective replacement box.

Furthermore, the camera device further comprises an adjusting connecting rack. The side fill light is connected to a top end of the display module through the adjusting connecting rack.

Furthermore, a brightness adjustment button and a color temperature adjustment button are disposed on the side fill light.

Furthermore, the foldable support frame comprises a first frame and a second frame, and the first frame is rotatably connected to the second frame. Two ends of the tray are respectively connected to a first end of the first frame and a first end of the second frame. A second end of the first frame and a second end of the second frame are defined as rotating ends. A projection of the first frame, the second frame, and the tray is triangular.

Furthermore, the camera device further comprises balance brackets, and each of the universal wheels is connected to the foldable support frame through a corresponding one of the balance brackets.

Furthermore, a light transmittance of the light-transmitting mirror layer is 45% to 55%.

Furthermore, the camera device further comprises at least one speaker electrically connected to the main control module. The at least one speaker is disposed in the display module, and sound transmission holes corresponding to the at least one speaker are defined on the rear cover plate.

Furthermore, the front fill light is disposed in a housing of the display module. An area of the light-transmitting mirror layer corresponding to the front fill light has a light transmittance of 95% to 100%. The operation interaction module comprises a switch electrically connected to the front fill light. The switch is disposed on the light-transmitting mirror layer and is configured to turn on and turn off the front fill light.

Furthermore, the camera device further comprises a printer. The printer is placed on the tray.

Furthermore, the front fill light is electrically connected to the main control module and the operation interaction module.

Furthermore, the front fill light is a silicone light strip.

Compared with the prior art, the present disclosure provides the camera device easy to assemble and transport. After a user is satisfied with a captured photo displayed on the display screen, the user is able to control the printer through the operation interaction module to print out a physical photo.

The side fill light, the camera module, and the foldable support frame are detachably connected to the display module, the tray is detachably connected to the foldable support frame, and the universal wheels are detachably connected to the lower end of the foldable support frame. These detachably connected configurations may be implemented by using screws and nuts. Through a detachable design, main components of the camera device are modularized. Detachable components of the camera device are in a separated state during transportation, which facilitates transport. Upon arriving at a destination, the detachable components are easily assembled into the camera device. Furthermore, during subsequent maintenance of the camera device, any of the detachable components is allowed to be replaced individually.

### BRIEF DESCRIPTION OF DRAWINGS

FIG. 1 is a schematic diagram of a camera device easy to assemble and transport according to one embodiment of the present disclosure.

FIG. 2 is another schematic diagram of the camera device according to one embodiment of the present disclosure.

FIG. 3 is an exploded schematic diagram of the camera device according to one embodiment of the present disclosure.

FIG. 4 is a schematic diagram of a side fill light and an adjusting connecting rack of the camera device according to one embodiment of the present disclosure.

FIG. 5 is an exploded schematic diagram of a camera module of the camera device according to one embodiment of the present disclosure.

FIG. 6 is a schematic diagram of a display module of the camera device according to one embodiment of the present disclosure.

FIG. 7 is a schematic diagram of a foldable support frame, universal wheels, a tray, and balance brackets of the camera device according to one embodiment of the present disclosure.

In the drawings: 1-display module; 110-light-transmitting mirror layer; 111-image-capturing opening; 120-display screen; 130-support middle frame; 140-support skeleton; 150-rear cover plate; 151-sound transmission hole; 2-camera module; 210-protective replacement box; 211-locking door; 220-adjusting base; 230-capturing camera; 3-side fill light; 310-brightness adjustment button; 320-color temperature adjustment button; 4-foldable support frame; 410-first frame; 420-second frame; 5-universal wheel; 6-tray; 7-main control module; 8-adjusting connecting rack; 9-front fill light; 10-balance brackets 11-speaker; 12-independent touch button area.

### DETAILED DESCRIPTION

Technical solutions in the embodiments of the present disclosure will be clearly and completely described below in conjunction with the accompanying drawings in the embodiments of the present disclosure. Obviously, the described embodiments are only a part of the embodiments of the present disclosure, rather than all of the embodiments. Based on the embodiments of the present disclosure, all other embodiments obtained by those of ordinary skill in the art without creative work shall fall within the protection scope of the present disclosure. It is understood that the drawings are only provided for reference and illustration, and are not used to limit the present disclosure. The connection relationship shown in the drawings is only for the convenience of clear description, and does not intend to limit the connection mode.

It should be noted that when a component is considered to be "connected" to another component, it can be directly connected to another component, or there may be a centered component at the same time. Unless otherwise defined, all technical and scientific terms used herein have the same meaning as commonly understood by those skilled in the art of the present disclosure. It should be noted in the description of the present disclosure that, unless otherwise regulated and defined, terms such as "installation", "bonded", and "connection" shall be understood in a broad sense, and, for example, may refer to fixed connection or detachable connection or integral connection; may refer to mechanical connection or electrical connection; and may refer to direct connection or indirect connection through an intermediate medium or inner communication of two elements. For those of ordinary skill in the art, the meanings of the above terms in the present disclosure may be understood according to concrete conditions.

In addition, it should be noted that in the description of the present disclosure, terms such as "central", "horizontal", "upper", "lower", "left", "right", "vertical", "horizontal", "top", "bottom", "inner", "outer", etc. indicate direction or position relationships shown based on the drawings, and are only intended to facilitate the description of the present disclosure and the simplification of the description rather than to indicate or imply that the indicated device or element must have a specific direction or be constructed and operated in a specific direction, and therefore, shall not be understood as a limitation to the present disclosure. In addition, terms such as "first", "second", and "third" are only used for the purpose of description, rather than being understood to indicate or imply relative importance.

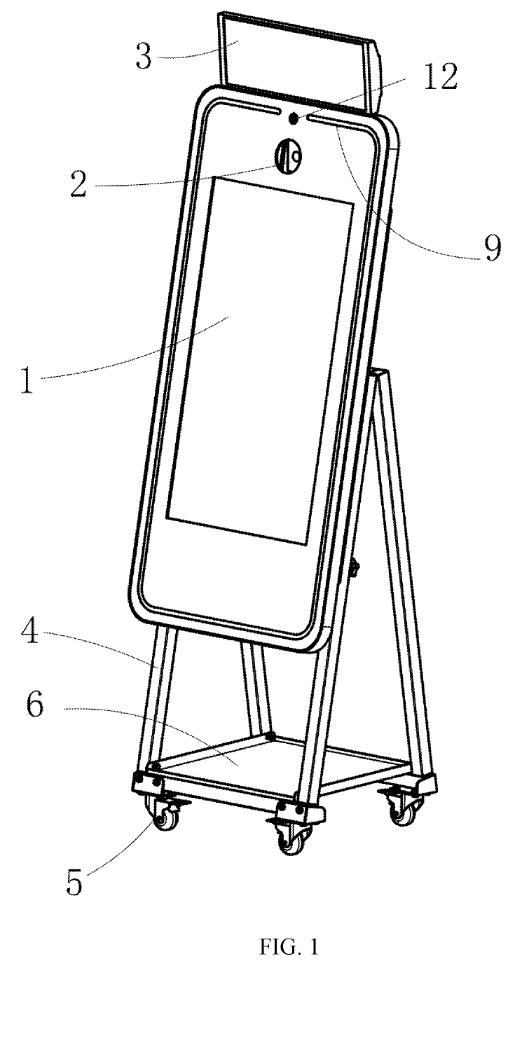

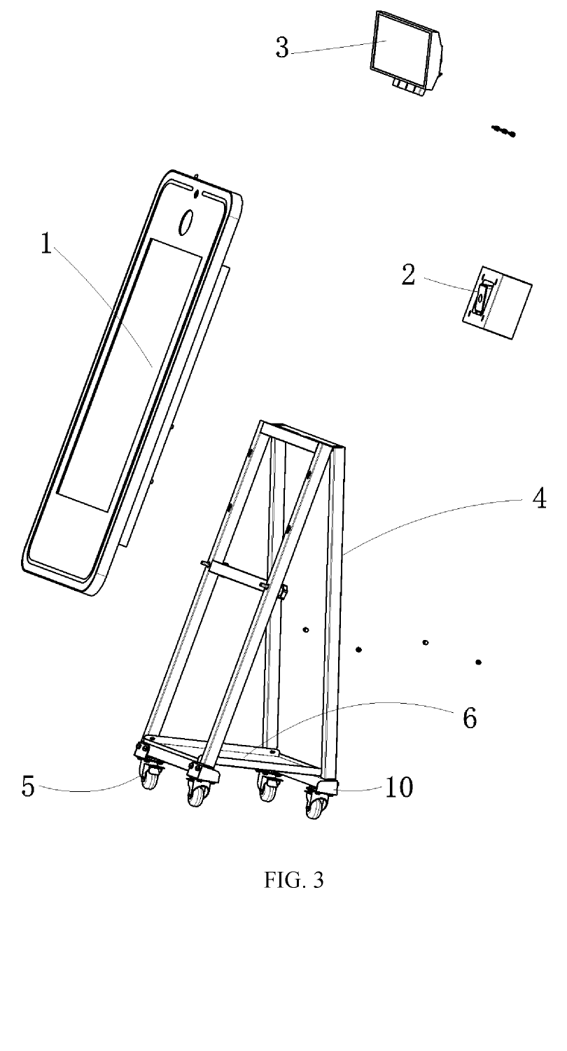

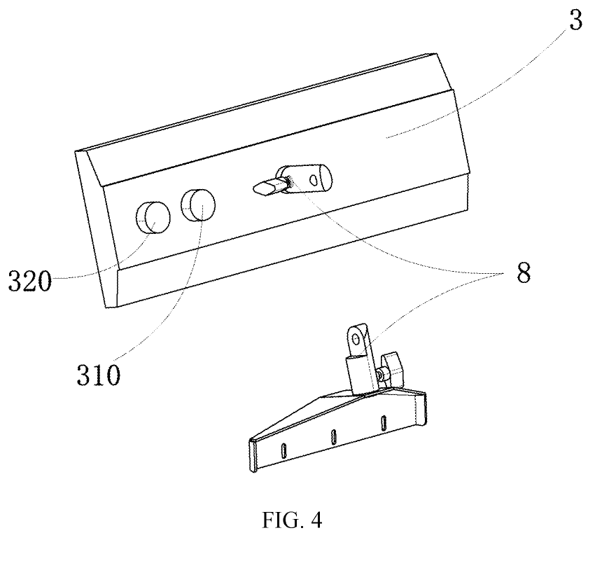

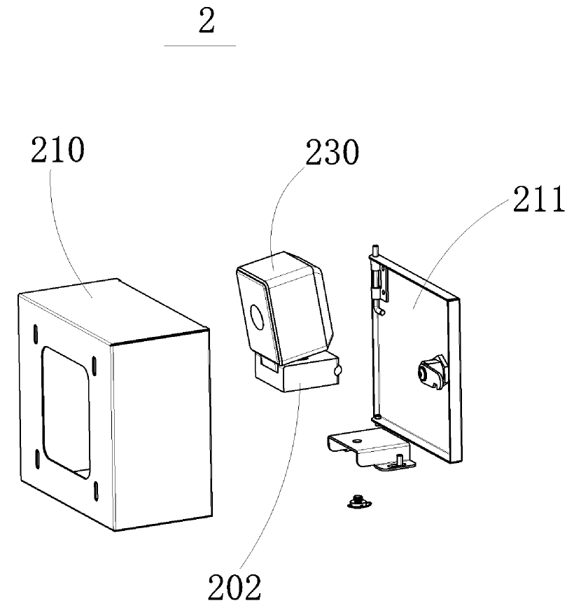

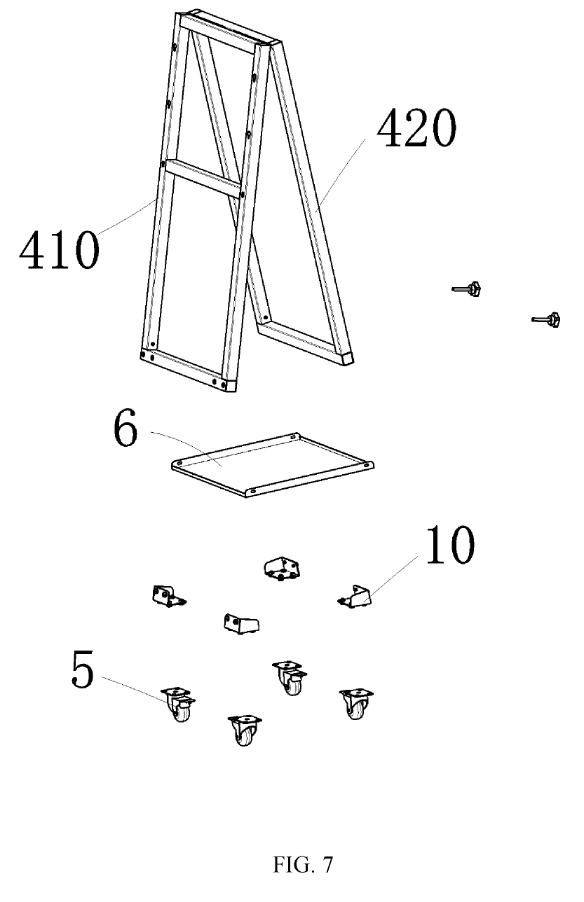

As shown in FIGS. 1-7, the present disclosure provides a camera device easy to assemble and transport to solve technical problems in the prior art.

The camera device easy to assemble and transport comprises a display module 1, a display module 2, a side fill light 3, a foldable support frame 4, universal wheels 5, a tray 6, a printer (not shown), and a main control module 7. A light-transmitting mirror layer 110 is disposed on an end surface of the display module 1. A display screen 120 is disposed adjacent to the light-transmitting mirror layer 110.

In some embodiments, the light-transmitting mirror layer 110 is made of glass, or the light-transmitting mirror layer 110 is made of an alternative material with transparent and light-transmitting properties, such as acrylic.

The display screen 120 may be attached to the light-transmitting mirror layer 110 or may have a certain spacing therefrom.

The display module 2 is detachably connected to the display module 1.

The side fill light 3 is disposed on a side end of the display module 1 and detachably connected to the display module 1.

The foldable support frame 4 is detachably connected to a rear side of the display module 1. The universal wheels 5 are detachably connected to a lower end of the foldable support frame 4, so that the camera device is movable.

The tray 6 is detachably connected to the foldable support frame 4 when the foldable support frame 4 is unfolded. The tray 6 is configured to keep the foldable support frame 4 in a fixed unfolded state.

The printer is placed on the tray 6 to avoid the display module 1 being too thick due to a need to house the printer. If the printer is fixed in the display module, the camera device is inconvenient to move.

The main control module 7 is disposed in the display module 1. The display screen 120 and the display module 2 are electrically connected to the main control module 7. An operation interaction module electrically connected to the main control module 7 is disposed on an end surface of the light-transmitting mirror layer 110.

The camera device may be placed, by a merchant, at a best photo-taking spot in a scenic area to facilitate locating by a user. Moreover, the camera device is easy to operate, allowing the user to use it immediately. During a photo-taking stage, the display screen 120 is in an off state and does not work, and the user is able to use a large display area of the light-transmitting mirror layer 110 as a mirror to adjust photo-taking poses. Through light compensation from the side fill light 3, the camera module 2 captures a corresponding photo. Subsequently, the display screen 120 displays a captured photo.

In some embodiments, the operation interaction module is a touch screen disposed on a surface of the light-transmitting mirror layer 110, or may be a physical button. In addition to displaying photos captured by the user, the display screen 120 further displays an interaction operation page. The main control module 7 may be a motherboard or a host in the prior art, which has an operating system in the prior art and interaction software specially provided by a manufacturer, so as to implement control of the display screen 120, the camera module 2, and the printer.

Since the light-transmitting mirror layer 110 has a light-transmitting function, the user is able to observe the captured photo displayed on the display screen 120 behind the light-transmitting mirror layer 110 without obstruction. The light-transmitting mirror layer 110 further provides protection for the display screen 120, and the display screen 120 does not need to be designed with a large area to serve as the mirror when the user takes photos, thereby saving equipment costs.

After the user is satisfied with the captured photo displayed on the display screen 120, the user is able to control the printer through the operation interaction module to print out a physical photo, thereby completing the use of the camera device.

The side fill light 3, the display module 2, and the foldable support frame 4 are detachably connected to the display module 1; the tray 6 is detachably connected to the foldable support frame 4, and the universal wheels 5 are detachably connected to the lower end of the foldable support frame 4. These detachably connected configurations may be implemented by using screws and nuts. Through a detachable design, main components of the camera device are modularized. Detachable components of the camera device are in a separated state during transportation, which facilitates transport. Upon arriving at a destination, the detachable components are easily assembled into the camera device. Furthermore, during subsequent maintenance of the camera device, any of the detachable components is allowed to be replaced individually.

In some embodiments, the tray 6 is further configured to hold an Android host or a computer host, and the main control module 7 comprises at least one connecting interface matched with the Android host and/or the computer host.

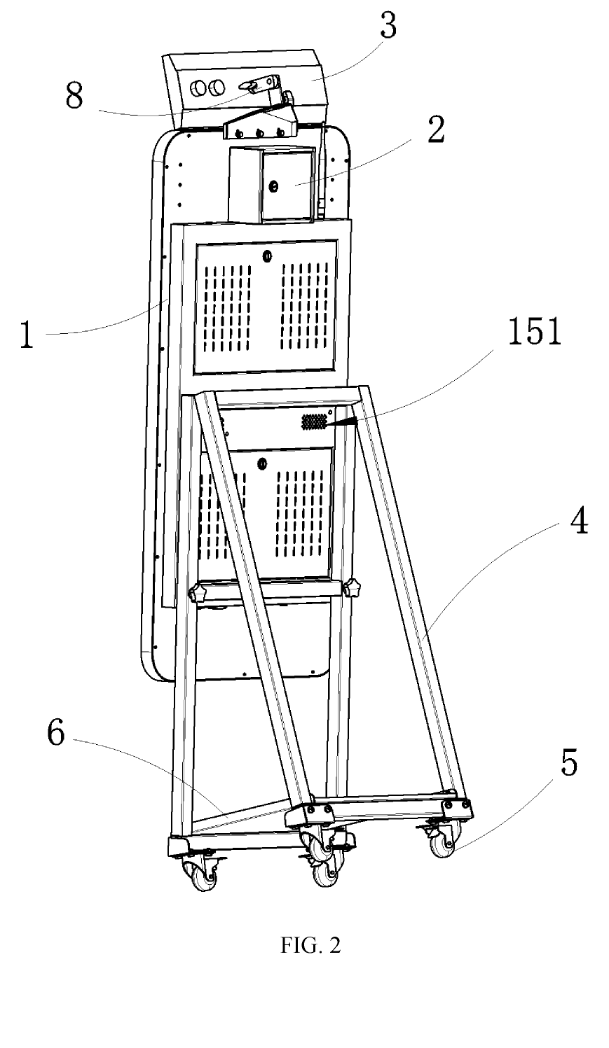

As shown in FIGS. 1-2, the display module 1 is rectangular and tilted at an angle of 70°.

The display module 1 has a rectangular shape and is disposed in an upright state. A tilt angle of the display module 1 is 70°, that is, tilt angles of the light-transmitting mirror layer 110 and the display screen 120 are 70°. From the perspective of ergonomics, the tile angle of the display module 1 fits a standard human body height to achieve a more comfortable visual and operation experience.

As shown in FIGS. 1-2 and 6, the display module 1 further comprises a support middle frame 130, a support skeleton 140, and a rear cover plate 150. The light-transmitting mirror layer 110 and the rear cover plate 150 are respectively disposed on two end surfaces of the support middle frame 130. The support skeleton 140 is enclosed by the light-transmitting mirror layer 110 and the support middle frame 130. The support skeleton 140 is connected to the support middle frame 130. The display screen 120 and the main control module 7 are mounted on the support skeleton 140.

As shown in FIGS. 1-2 and 5, the display module 2 comprises a protective replacement box 210, an adjusting base 220, and a capturing camera 230. The adjusting base 220 and the capturing camera 230 are disposed in the protective replacement box 210. The capturing camera 230 is connected to the protective replacement box 210 through the adjusting base 220. The protective replacement box 210 is detachably connected to the rear cover plate 150. The light-transmitting mirror layer 110 comprises a image-capturing opening 111 corresponding to the capturing camera 230. A locking door 211 is rotatably connected to the protective replacement box 210.

The adjusting base 220 is configured to adjust front-to-rear positions and a tilt angle of the capturing camera 230, so that the adjustment of a capturing area better meets user requirements.

By simply using a corresponding key to open the locking door 211, the capturing camera is allowed to be mounted and maintained without disconnecting the protective replacement box 210 from the rear cover plate 150.

Furthermore, the camera device further comprises an adjusting connecting rack 8. The side fill light 3 is connected to a top end of the display module 1 through the adjusting connecting rack 8. A brightness adjustment button 310 and a color temperature adjustment button 320 are disposed on the side fill light 3.

The adjusting connecting rack 8 allows for 360° horizontal and 340° vertical adjustment of a light angle of the side fill light 3.

As shown in FIG. 1, the camera device further comprises a front fill light 9. The front fill light 9 is in a closed ring shape or a non-closed ring shape, and the front fill light 9 is disposed along edges of the display module 1 or adjacent to the edges of the display module 1. The front fill light 9 is electrically connected to the main control module 7 and the operation interaction module.

In some embodiments, the front fill light 9 is disposed in a housing of the display module 1. An area of the light-transmitting mirror layer 110 corresponding to the front fill light 9 has a light transmittance of 95% to 100%. The operation interaction module comprises a switch electrically connected to the front fill light 9, the switch is disposed on the light-transmitting mirror layer 110 and is configured to turn on and turn off the front fill light 9.

The operation interaction module comprises an independent touch button area 12, and the independent touch button area 12 is a switch controlling switching on and off of the front fill light 9. The front fill light 9 is a silicone light strip.

In some embodiments, the camera device further comprises a light controller, and the light controller controls the switching on and off of the front fill light 9.

By providing the front fill light 9, a shortcoming that the side fill light 3 is only able to provide fill light for a head and a chest of the user but is unable to provide fill light for parts below the chest of the user is compensated for, so that a light effect is better when taking a full-body photo for the user.

As shown in FIGS. 1, 2 and 7, the foldable support frame 4 comprises a first frame 410 and a second frame 420, and the first frame 410 is rotatably connected to the second frame 420. Two ends of the tray 6 are respectively connected to a first end of the first frame 410 and a first end of the second frame 420. A second end of the first frame 410 and a second end of the second frame 420 are defined as rotating ends. A projection of the first frame 410, the second frame 420, and the tray 6 is triangular, so that the tray 6, the first frame, and the second frame are stably connected.

In some embodiments, the first frame 410 is a rectangular frame with a crossbar in a middle thereof. The second frame 420 is a square frame.

The first frame 410 is connected to the rear cover plate 150 by hand-tightening screws.

As shown in FIGS. 1, 2 and 7, the camera device further comprises balance brackets 10. The universal wheels 5 are connected to the foldable support frame 4 through the balance brackets 10.

Mechanical products have manufacturing tolerances, or the camera device may be placed in a location with uneven ground, such as a lawn at the scenic spot. Therefore, each of the balance brackets 10 is disposed between a corresponding one of the universal wheels 5 and the foldable support frame 4, so as to adjust a fit between a lowermost end of the camera device and the ground, so that the universal wheels 5 are not suspended but are stably disposed on the ground. In some embodiments, each of the balance brackets 10 is an angle iron block with an adjustment screw thereon, and a distance between each of the universal wheels 5 and a corresponding angle iron block is adjusted through a corresponding adjustment screw to achieve balance adjustment. The balance brackets 10 are further connected to the tray 6.

Optionally, a light transmittance of the light-transmitting mirror layer 110 is 45% to 55%.

By setting the light-transmitting of the light-transmitting mirror layer 110 to be 45% to 55%, the user is able to comfortably observe content displayed on the display screen 120 behind the light-transmitting mirror layer 110. At the same time, an image of a user is reflected through the light-transmitting mirror layer 110 due to mirror characteristics of the light-transmitting mirror layer 110, thereby creating better shooting conditions to achieve a better shooting effect.

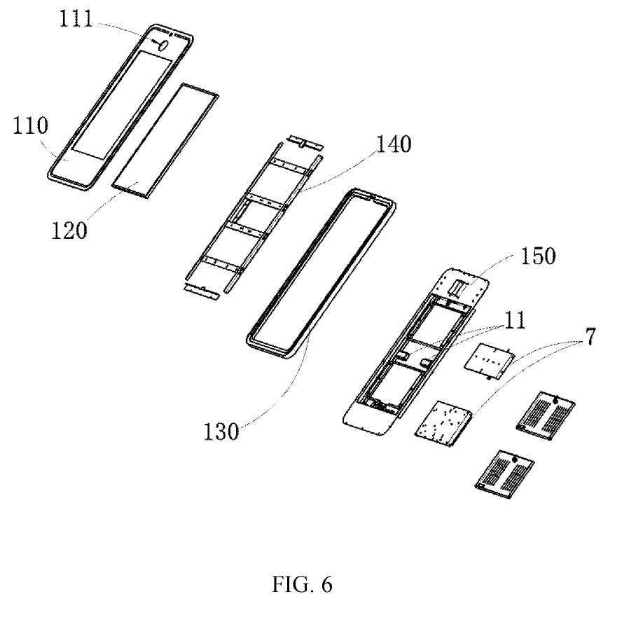

As shown in FIGS. 2 and 6, the camera device further comprises speakers 11 electrically connected to the main control module 7. The speakers 11 are disposed in the display module 1, and sound transmission holes 151 corresponding to the speakers 11 are defined on the rear cover plate 150.

The main control module 7 is configured to control the speakers 11 to play preset audio to attract customers to use the camera device. The speakers are further able to play introductory audio to guide the customers on how to use the camera device.

In the specification and claims of the present disclosure, terms "include/comprise" and terms "have/contain" and their variants are used to designate existence of stated features, values, steps or components, but do not exclude the existence or addition of one or multiple other features, values, steps, components, or combinations thereof.

For clarity of explanation, some features of the present disclosure are described in different embodiments. However, these features can also be combined and described in a single embodiment. Moreover, some features of the present disclosure are only described in a single embodiment for the sake of brevity. However, these features can also be described in different embodiments separately or in any suitable combination.

Foregoing descriptions are only optional embodiments of the present disclosure and are not intended to limit the present disclosure. Any modification, equivalent replacement, or improvement within the technical scope of the present disclosure should be included in the protection scope of the present disclosure.

What is claimed is:

1. A camera device easy to assemble and transport, comprising:
a display module;
a camera module;
a side fill light;
a front fill light;
a foldable support frame;
universal wheels;
a tray; and
a main control module;
wherein a light-transmitting mirror layer is disposed on an end surface of the display module, and a display screen is disposed adjacent to the light-transmitting mirror layer;
wherein the camera module is detachably connected to the display module, and the side fill light is disposed on a side end of the display module and detachably connected to the display module;
wherein the foldable support frame is detachably connected to a rear side of the display module, the universal wheels are detachably connected to a lower end of the foldable support frame, and the tray is detachably connected to the foldable support frame when the foldable support frame is unfolded;
wherein the main control module is disposed in the display module, the display screen and the camera module are electrically connected to the main control module, and an operation interaction module electrically connected to the main control module is disposed on an end surface of the light-transmitting mirror layer;
wherein the front fill light is in a closed ring shape or a non-closed ring shape, and the front fill light is disposed along edges of the display module or adjacent to the edges of the display module.

2. The camera device according to claim 1, wherein the display module is rectangular and tilted at an angle of 70°.

3. The camera device according to claim 1, wherein the display module further comprises a support middle frame, a support skeleton, and a rear cover plate;
wherein the light-transmitting mirror layer and the rear cover plate are respectively disposed on two end surfaces of the support middle frame, the support skeleton is enclosed by the light-transmitting mirror layer and the support middle frame, the support skeleton is connected to the support middle frame, and the display screen and the main control module are mounted on the support skeleton.

4. The camera device according to claim 3, wherein the camera module comprises a protective replacement box, an adjusting base, and a capturing camera;
wherein the adjusting base and the capturing camera are disposed in the protective replacement box, and the capturing camera is connected to the protective replacement box through the adjusting base;
wherein the protective replacement box is detachably connected to the rear cover plate, the light-transmitting mirror layer comprises a image-capturing opening corresponding to the capturing camera, and a locking door is rotatably connected to the protective replacement box.

5. The camera device according to claim 1, wherein the camera device further comprises an adjusting connecting rack, the side fill light is connected to a top end of the display module through the adjusting connecting rack.

6. The camera device according to claim 1, wherein a brightness adjustment button and a color temperature adjustment button are disposed on the side fill light.

7. The camera device according to claim 1, wherein the foldable support frame comprises a first frame and a second frame, and the first frame is rotatably connected to the second frame;
wherein two ends of the tray are respectively connected to a first end of the first frame and a first end of the second frame, a second end of the first frame and a second end of the second frame are defined as rotating ends, and a projection of the first frame, the second frame, and the tray is triangular.

8. The camera device according to claim 1, wherein the camera device further comprises balance brackets, and each of the universal wheels is connected to the foldable support frame through a corresponding one of the balance brackets.

9. The camera device according to claim 1, wherein a light transmittance of the light-transmitting mirror layer is 45% to 55%.

10. The camera device according to claim 3, wherein the camera device further comprises at least one speaker electrically connected to the main control module;
wherein the at least one speaker is disposed in the display module, and sound transmission holes corresponding to the at least one speaker are defined on the rear cover plate.

11. The camera device according to claim 1, wherein the front fill light is disposed in the display module, and an area of the light-transmitting mirror layer corresponding to the front fill light has a light transmittance of 95% to 100%;
wherein the operation interaction module comprises a switch electrically connected to the front fill light, the switch is disposed on the light-transmitting mirror layer and is configured to turn on and turn off the front fill light.

12. The camera device according to claim 1, wherein the camera device further comprises a printer, and the printer is placed on the tray.

13. The camera device according to claim 1, wherein the front fill light is electrically connected to the main control module and the operation interaction module.

14. The camera device according to claim 1, wherein the front fill light is a silicone light strip.

15. A camera device easy to assemble and transport, comprising:
a display module;
a camera module;
a foldable support frame;
universal wheels;
a tray;
a main control module; and
a front fill light;
wherein a light-transmitting mirror layer is disposed on an end surface of the display module, and a display screen is disposed adjacent to the light-transmitting mirror layer;
wherein the camera module is detachably connected to the display module;
wherein the foldable support frame is detachably connected to a rear side of the display module, the universal wheels are detachably connected to a lower end of the foldable support frame, and the tray is detachably connected to the foldable support frame when the foldable support frame is unfolded;
wherein the main control module is disposed in the display module, the display screen and the camera module are electrically connected to the main control module, and an operation interaction module electrically connected to the main control module is disposed on an end surface of the light-transmitting mirror layer;
wherein the front fill light is in a closed ring shape or a non-closed ring shape, and the front fill light is disposed along edges of the display module or adjacent to the edges of the display module.

16. The camera device according to claim 15, wherein the camera device further comprises a side fill light and an adjusting connecting rack;
wherein the side fill light is disposed on a side end of the display module and detachably connected to the display module, and the side fill light is connected to a top end of the display module through the adjusting connecting rack;
wherein a brightness adjustment button and a color temperature adjustment button are disposed on the side fill light.

17. The camera device according to claim 15, wherein the camera device further comprises balance brackets, and each of the universal wheels is connected to the foldable support frame through a corresponding one of the balance brackets.

18. A camera device easy to assemble and transport, comprising:
a display module;
a camera module;
a front fill light;
a side fill light;
a support frame;
universal wheels;
a tray; and
a main control module;
wherein a light-transmitting mirror layer is disposed on an end surface of the display module, and a display screen is disposed adjacent to the light-transmitting mirror layer;
wherein the camera module is detachably connected to the display module, and the side fill light is disposed on a side end of the display module and detachably connected to the display module;
wherein the universal wheels are detachably connected to a lower end of the support frame, and the tray is detachably connected to the support frame;
wherein the main control module is disposed in the display module, the display screen and the camera module are electrically connected to the main control module, and an operation interaction module electrically connected to the main control module is disposed on an end surface of the light-transmitting mirror layer;
wherein the front fill light is in a closed ring shape or a non-closed ring shape, and the front fill light is disposed along edges of the display module or adjacent to the edges of the display module.

19. The camera device according to claim 18, wherein the camera device further comprises an adjusting connecting rack, and the side fill light is connected to a top end of the display module through the adjusting connecting rack;
wherein a brightness adjustment button and a color temperature adjustment button are disposed on the side fill light.

20. The camera device according to claim 18, wherein the camera device further comprises balance brackets, and each of the universal wheels is connected to the foldable support frame through a corresponding one of the balance brackets.
